(19) United States
(12) Patent Application Publication
(10) Pub. No.: US 2013/0271233 A1
(43) Pub. Date: Oct. 17, 2013

(54) APPARATUS AND METHOD OF TUNING MICROWAVE FILTER

(71) Applicant: ELECTRONICS AND TELECOMMUNICATIONS RESEARCH INSTITUTE, Daejeon (KR)

(72) Inventors: Chang Soo KWAK, Daejeon (KR); Man Seok UHM, Daejeon (KR); In Bok YOM, Daejeon (KR)

(73) Assignee: Electronics And Telecommunications Research Institue, Daejeon (KR)

(21) Appl. No.: 13/862,593

(22) Filed: Apr. 15, 2013

(30) Foreign Application Priority Data
Apr. 16, 2012 (KR) 10-2012-0039282
Sep. 14, 2012 (KR) 10-2012-0102001

(51) Int. Cl. H04B 3/04

(52) U.S. Cl. CPC H03H 7/0153
USPC 333/17.1

(57) ABSTRACT

Disclosed are an apparatus and a method of tuning a microwave filter. An apparatus for tuning a microwave filter according to the present invention includes: a measurement device configured to measure a scattering (S) parameter curve of a microwave filter desired to be tuned; a control device configured to perform tuning so that a shape of the S parameter curve according to a movement of a preselected tuning screw is matched to a shape of a target S parameter curve, and then determine a quantity of transfer of the tuning screw based on feature points on the S parameter curve by using a least squares method in which a preset weight is reflected; and a tuning device configured to move the tuning screw based on the determined quantity of transfer of the tuning screw.

### CROSS-REFERENCE TO RELATED APPLICATIONS

This application claims priority to and the benefit of Korean Patent Application No. 10-2012-0039282 filed in the Korean Intellectual Property Office on Apr. 16, 2012 and Korean Patent Application No. 10-2012-0102001 filed in the Korean Intellectual Property Office on Sep. 14, 2012, the entire contents of which are incorporated herein by reference.

### TECHNICAL FIELD

The present invention relates to a method of tuning a microwave filter. More particularly, the present invention relates to an apparatus and a method of automatically tuning a microwave filter, which tunes a shape so that a shape of an S parameter curve according to a movement of a tuning screw is matched to a shape of a target S parameter curve, and finely tunes a feature point of the S parameter curve by using a least squares square method in which a weight is reflected.

### BACKGROUND ART

A method of tuning a microwave filter includes a method of tuning a filter by a parameter extraction method among the methods suggested in the related art. The method of tuning the filter is a method of extracting parameters exhibiting a character of the filter in a current state, comparing values of the parameters with designed parameter values, and then adjusting a tuning factor, that is, a tuning screw, so that a difference becomes 0. However, the method extracts the parameter by using an optimization method. However, in a case of the optimization based on a gradient, there is a problem of having a local minimum point, and in a case in which a global optimization method is used, there is a disadvantage in that a calculation time increases.

The method of tuning the microwave filter also includes a method of tuning a filter by using a reference filter among other methods suggested in the related art. In the method of tuning the filter, tuning screws of the reference filter and a filter to be tuned are all removed, one tuning screw of the reference filter is inserted as much as the quantity of a designed value to measure a scattering (S) parameter, and then a tuning screw corresponding to the tuning screw inserted in the reference filter is inserted in the filter to be tuned so that the filter to be tuned has the same S parameter as that of the reference filter. The process is repeatedly performed on the residual tuning residuals. However, in order to use the aforementioned method, it is essentially necessary to include a reference filter of which the tuning has been already completed, and other values, except for the values of the tuning screws, needs to have minimal difference for various types of product. In the aforementioned method, an error is accumulated in a tuning screw inserted later, so that as an order of the filter increases, tuning accuracy is deteriorated.

The method of tuning the microwave filter also includes a method of tuning a filter by using a global optimization method among yet other methods suggested in the related art. The method of tuning the microwave filter is a method of adjusting a tuning screw so that an S parameter at a specific frequency has a desired value by using a global optimization method, not based on a model of a filter. The aforementioned method has a disadvantage in that the measurement needs to be performed excessively many times, and the number of variables, that is, the number of times of the measurement is exponentially increased whenever the number of tuning screws increases as well.

In order to achieve desired performance with the microwave filter, it is necessary to process the microwave filter according to a design and then finally manually tune the microwave filter by a person. The reason is that a model used in the design is not complete, or processing accuracy does not sufficiently met to a necessary degree. Necessity of the final tuning by a user is more highly demanded as a used frequency is high or an order of a filter is high, thereby causing an increase in a manufacturing time and an increase in a price of a product.

### SUMMARY OF THE INVENTION

The present invention has been made in an effort to provide an apparatus and a method of automatically tuning a microwave filter, which tunes a shape so that a shape of an S parameter curve according to a movement of a tuning screw is matched to a shape of a target S parameter curve, and finely tunes a feature point of the S parameter curve by using a least squares square method in which a weight is reflected, in which a mechanism of tuning a filter by a person is implemented by a computer.

However, an object of the present invention is not limited to the aforementioned matters, and those skilled in the art will clearly understand non-mentioned other objects through the following description.

An exemplary embodiment of the present invention provides an apparatus for tuning a microwave filter including: a measurement device configured to measure a scattering (S) parameter curve of a microwave filter desired to be tuned; a control device configured to perform tuning so that a shape of the S parameter curve according to a movement of a preselected tuning screw is matched to a shape of a target S parameter curve, and then determine a quantity of transfer of the tuning screw based on feature points on the S parameter curve by using a least squares square method in which a preset weight is reflected; and a tuning device configured to move the tuning screw based on the determined quantity of transfer of the tuning screw.

The control device may move the tuning screws of the microwave filter to initial positions, record movements of the feature points on the S parameter curve according to the movements of the tuning screws, and then selectively select the tuning screws in order of the amount of influence exerted on the feature points according to the movements of the feature points.

The control device may include: a coarse tuning unit configured to perform tuning so that a first S parameter curve corresponding to a curve of a transmission coefficient according to a movement of the tuning screw is matched to a first target S parameter curve, and then perform tuning so that a second S parameter curve corresponding to a curve of a reflection coefficient is matched to a second target S parameter curve; and a fine tuning unit configured to, when feature points positioned on the second S parameter curve are generated as many as the number of feature points on the second target S parameter curve, measure sensitivity and errors of the generated feature points on the second S parameter curve, and determine a quantity of movement of the tuning screw by a least squares method in which a weight is reflected based on the measured sensitivity and error.

The coarse tuning unit may move the tuning screws of the microwave filter to initial positions, record movements of zeros of transmission coefficient according to the movements of the tuning screws, and then selectively select the tuning screws in order of the amount of influence exerted on the zeros of the transmission coefficient based on the movements of the zeros of the transmission coefficient.

The coarse tuning unit may perform first coarse tuning so that a shape of the first S parameter curve is matched to a shape of the first target S parameter curve by moving the tuning screws, calculate shape similarity between the first S parameter curve on which the first coarse tuning is performed and the curve of the first target S parameter curve and determine whether the calculated shape similarity is larger than a preset value when all feature points are not generated after the first coarse tuning, and perform second coarse tuning by moving the tuning screw so that a shape of the second S parameter curve is matched to a shape of the second target S parameter curve when the shape similarity is larger than the preset value as a result of the determination.

The shape tuning unit may perform the first coarse tuning by moving the tuning screws again so that the shape of the first S parameter curve is matched to the shape of the first target S parameter curve, When the shape similarity is equal to or smaller than the preset value as a result of the determination.

The shape tuning unit may measure sensitivity and errors of the feature points on the second S parameter curve by moving the tuning screws, and determine a quantity of transfer of the tuning screws based on the measured sensitivity and errors by a least squares method in which a weight is reflected, When all feature points are generated after the first coarse tuning.

The feature points may include at least one among zeros of a transmission coefficient, zeros of a reflection coefficient, and a local maximum point within a bandwidth.

Another exemplary embodiment of the present invention provides a method of tuning a microwave filter, including: measuring a scattering (S) parameter curve of a microwave filter desired to be tuned; performing tuning so that a shape of the S parameter curve according to a movement of a preselected tuning screw is matched to a shape of a target S parameter curve, and then determining a quantity of transfer of the tuning screw based on feature points on the S parameter curve by using a least squares method in which a preset weight is reflected; and moving the tuning screw based on the determined quantity of transfer of the tuning screw.

The performing may comprise: moving the tuning screws of the microwave filter to initial positions, recording movements of the feature points on the S parameter curve according to the movements of the tuning screws, and selectively selecting the tuning screws in order of the amount of influence exerted on the feature points according to the movements of the feature points.

The performing may comprise: performing tuning so that a first S parameter curve corresponding to a curve of a transmission coefficient according to a movement of the tuning screw is matched to a first target S parameter curve, and performing tuning so that a second S parameter curve corresponding to a curve of a reflection coefficient is matched to a second target S parameter curve; and measuring sensitivity and errors of the generated feature points on the second S parameter curve, and determining a quantity of movement of the tuning screw by a least squares method in which a weight is reflected based on the measured sensitivity and error, when feature points positioned on the second S parameter curve are generated as many as the number of feature points on the second target S parameter curve.

The performing may comprise: moving the tuning screws of the microwave filter to initial positions, recording movements of zeros of transmission coefficient according to the movements of the tuning screws, and selectively selecting the tuning screws in order of the amount of influence exerted on the zeros of the transmission coefficient based on the movements of the zeros of the transmission coefficient.

The performing may comprise: performing first coarse tuning that a shape of the first S parameter curve is matched to a shape of the first target S parameter curve by moving the tuning screws, calculating shape similarity between the first S parameter curve on which the first coarse tuning is performed when all feature points are not generated after the first coarse tuning and determining the curve of the first target S parameter curve may be calculated and whether the calculated shape similarity is larger than a preset value, and moving the tuning screw and performing second coarse tuning that a shape of the second S parameter curve is matched to a shape of the second target S parameter curve, when the shape similarity is larger than the preset value as a result of the determination.

The performing may comprise: moving the tuning screws again and performing the first coarse tuning that the shape of the first S parameter curve is matched to the shape of a target S1 parameter curve, When the shape similarity is equal to or smaller than the preset value as a result of the determination.

The performing may comprise: measuring sensitivity and errors of the feature points on the second S parameter curve by moving the tuning screws, and determining a quantity of transfer of the tuning screws based on the measured sensitivity and errors by a least squares method in which a weight is reflected, When all feature points are generated after the first coarse tuning.

The feature points may include at least one among zeros of a transmission coefficient, zeros of a reflection coefficient, and a local maximum point within a bandwidth.

According to the invention disclosed herein, the present invention may achieve the following effects by implementing a mechanism of tuning a filter by a computer, instead of a person.

First, a microwave filter may be automatically tuned. There is less risk of having a local minimum value which is a disadvantage of the optimization method, that is, a reflection coefficient or a transmission coefficient has a desired value in several determined specific frequencies, so that the present invention is appropriate for the automatic tuning.

Second, even fine tuning may be more flexibly, effectively, and rapidly completed with a filter. When final tuning is performed, it is necessary to memorize a change in an S parameter curve according to a movement of a tuning screw and adjust the tuning screws by synthetically determining the change. However, when a person performs the final tuning, there is a problem of forgetting and a poor synthetic determination ability. Since the present invention performs the final tuning, the tuning may be more effectively and rapidly performed.

Third, performance of a microwave filter may be optimized. The present invention performs the tuning based on a shape of a filter characteristic graph. Accordingly, when a processing of a part on which the tuning cannot be performed has an error which cannot be ignored, the present invention may achieve the best performance of the filter by adjusting a tuning screw.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a diagram illustrating an apparatus for tuning a microwave filter according to an exemplary embodiment of the present invention.

FIG. 2 is a diagram illustrating a detailed configuration of a control device 120 illustrated in FIG. 1.

FIG. 3 is a diagram for describing similarity in curves according to an exemplary embodiment of the present invention.

FIG. 4 is a diagram illustrating a method of tuning a microwave filter according to an exemplary embodiment of the present invention.

It should be understood that the appended drawings are not necessarily to scale, presenting a somewhat simplified representation of various features illustrative of the basic principles of the invention. The specific design features of the present invention as disclosed herein, including, for example, specific dimensions, orientations, locations, and shapes will be determined in part by the particular intended application and use environment.

In the figures, reference numbers refer to the same or equivalent parts of the present invention throughout the several figures of the drawing.

### DETAILED DESCRIPTION

Hereinafter, an apparatus and a method of tuning a microwave filter according to an exemplary embodiment of the present invention will be described with reference to the accompanying drawings, FIGS. 1 to 4. The present invention will be described in detail based on parts necessary to understand an operation and an effect according to the present invention.

In describing constituent elements of the present invention, different reference numbers may refer to like elements depending on the drawing, and like reference numerals may refer to like elements even though like elements are shown in different drawings. However, even in this case, it is not meant that a corresponding constituent element has a different function according to an exemplary embodiment or has the same function in different exemplary embodiments, and a function of each constituent element may be determined based on a description of each constituent element in a corresponding exemplary embodiment.

The present invention suggests a new method of tuning a shape so that a shape of an S parameter curve according to a movement of a tuning screw is matched to a shape of a target S parameter curve, and finely tuning a feature point of the S parameter curve by using a least squares square method in which a weight is reflected.

FIG. 1 is a diagram illustrating an apparatus for tuning a microwave filter according to an exemplary embodiment of the present invention.

As illustrated in FIG. 1, the apparatus for tuning a microwave filter according to the present invention may include a measurement device 110, a control device 120, a tuning device 130, and the like.

The measurement device 110 may measure an S parameter curve of a microwave filter to be tuned. A network analyzer and the like may be used as the measurement device 110.

The control device 120 may perform coarse tuning of recognizing a shape of an S parameter curve measured according to a movement of a tuning screw and then automatically performing the tuning so that the recognized shape of the S parameter curve is similar or matched to a shape of a target S parameter curve. Here, the S parameter curve may include a first S parameter curve corresponding to a curve of a transmission coefficient and a second S parameter curve corresponding to a curve of a reflection coefficient.

In this case, the control device 120 performs the tuning so that shape similarity between the measured S parameter curve and the target S parameter curve has a maximum value. Here, the shape similarity refers to a method of quantifying a degree of similarity of the shapes of the two curves regardless of relative positions of the two curves.

When the shape similarity between the two curves reaches a preset target value, the control device 120 may perform fine tuning of tuning a feature point of the S parameter curve by using a linear least squares square method in which a weight is reflected.

In this case, the feature point includes zeros of the transmission coefficients, zeros of the reflection coefficients, a local maximum point within a bandwidth, and the like. 1) The zeros of the transmission coefficient represent factors for determining a blocking characteristic of the filter, 2) both end points among the zeros of the reflection coefficient represent factors for determining a bandwidth, and the local maximum point represents a factor for determining reflection loss within the bandwidth.

In this case, the control device 120 needs to move the feature points of the S parameter curve to desired positions. That is, the control device 120 may measure sensitivity and an error of each of the feature points according to the movement of each of tuning screws, and determine a quantity of the movement of the tuning screw based on the measured sensitivity and error.

The tuning device 130 may automatically tune the microwave filter by moving the tuning screw based on the determined quantity of the movement of the tuning screw. The tuning device 130 for tuning the microwave filter has been described as an example, but it is not limited thereto, and may automatically tune an ultra microwave filter or a microwave filter, and various waveguide filters, diplexers, and multiplexers, as well as the microwave filter.

As such, the tuning device 130 enables a mechanism of tuning a filter to be performed by a computer, instead of a person, thereby more flexibly, effectively, and rapidly performing the fine tuning on the filter.

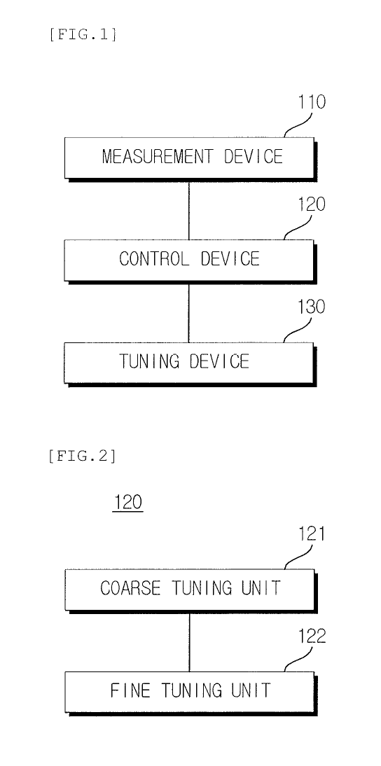

FIG. 2 is a diagram illustrating a detailed configuration of the control device 120 illustrated in FIG. 1.

As illustrated in FIG. 2, the control device 120 according to the present invention may include a coarse tuning unit 121 using shape similarity and a fine tuning unit 122 using value similarity.

The coarse tuning unit 121 may recognize a shape of an S parameter curve measured according to a movement of a tuning screw and then automatically perform the tuning so that the recognized shape of the S parameter curve is matched to a shape of a target S parameter curve.

First, the coarse tuning unit 121 moves tuning screws to initial positions, records movements of feature points according to the movements of the respective tuning screws, and then selectively selects the tuning screws which exert the amount of influence on the feature points according to the recorded movements of the feature points.

The coarse tuning unit 121 performs tuning so that a first S parameter curve corresponding to a curve of a transmission coefficient according to the movement of the selected tuning screw is matched to a first target S parameter curve, and then performs tuning so that a second S parameter curve corresponding to a curve of a reflection coefficient is matched to a second target S parameter curve.

In this case, when all preset feature points of the second S parameter curve are generated after performing the tuning so that the first S parameter curve is matched to the first target S parameter curve, the coarse tuning unit 121 does not perform a process of matching the second S parameter curve to the second target S parameter curve.

When all preset feature points of the second S parameter curve are generated, that is, the feature points positioned on the second S parameter curve are generated as many as the number of feature points on the second target second S parameter curve, the fine tuning unit 122 may measure sensitivity and errors of the generated feature points and determine the quantity of a movement of the tuning screw by the linear least squares square method based on the measured sensitivity and error.

In this case, since performance of the filter may be evaluated based on the feature points, a process of moving the points to desired positions by the fine tuning after the approximate coarse tuning is performed. A method of moving the feature points is as follows.

First, movements in an x-axis direction and a y-axis direction of the respective feature points are recorded by slightly moving the respective tuning screws. That is, sensitivity of the respective feature points for the respective tuning screws is measured, and the sensitivity of each feature point may be represented by matrix S of Equation 1 below.

$${[ \begin{matrix}{S}_{11 x} & {S}_{12 x} & ⋯ & {S}_{1 ( N - 1 ) x} & {S}_{1 Nx} \\ {S}_{11 y} & {S}_{12 y} & ⋯ & {S}_{1 ( N - 1 ) y} & {S}_{1 Ny} \\ ⋮ & ⋮ & ⋱ & ⋮ & ⋮ \\ {S}_{M 1 x} & {S}_{M 2 x} & ⋯ & {S}_{M ( N - 1 ) x} & {S}_{MNx} \\ {S}_{M 1 y} & {S}_{M 2 y} & ⋯ & {S}_{M ( N - 1 ) y} & {S}_{MNy}\end{matrix} ]}_{[ 2 M \times N ]}^{S} {( \begin{matrix}{T}_{1} \\ {T}_{2} \\ ⋮ \\ {T}_{N - 1} \\ {T}_{N}\end{matrix} )}_{\cdot ( N \times 1 )}^{\cdot t} {=}_{=}^{=} {( \begin{matrix}{Δ}_{1 x} \\ {Δ}_{1 y} \\ ⋮ \\ {Δ}_{Mx} \\ {Δ}_{My}\end{matrix} )}_{( 2 M \times 1 )}^{d} \qquad [ Equation 1 ]$$

Here, Sᵢⱼₓ or S_{ijy} is a value representing the quantity by which an i^{th} feature point moves in the x-axis direction or the y-axis direction when a j^{th} tuning screw moves by 1. Tⱼ means a movement of the j^{th} tuning screw, and Δᵢₓ or Δ_{iy} means an error in the x-axis direction or the y-axis direction of the i^{th} feature point in a given state. M is the number of feature points, and N is the number of tuning screws.

In order to move the respective feature points to the desired positions in such a given state, the quantity of transfer, that is, the direction and a quantity, which needs to be moved by the tuning screws may be calculated by calculating the aforementioned Equation 1. Equation 1 is an overdetermined linear simultaneous equation generally having more equations than unknown quantities. In this case, the quantity of transfer of the tuning screw may be obtained by using the least squares method.

However, importance of the respective feature points is different from each other. For example, it is necessary to maximally decrease an error in the x-axis direction (a frequency axis) between the zero of the first reflection coefficient and the zero of the last reflection coefficient for matching the bandwidth, but this is not that significant when the error in the y-axis direction of the zero of the reflection coefficient within the bandwidth is equal to or less than a predetermined value. Accordingly, in order to reflect relative importance, a weight is assigned to each feature point. Equation 2 below represents a matrix for assigning the weight, and a value considering the weight may be calculated by Equation 3.

$$W = {[ \begin{matrix}{w}_{1 x} & 0 & ⋯ & 0 & 0 \\ 0 & {w}_{1 y} & ⋯ & 0 & 0 \\ ⋮ & ⋮ & ⋱ & ⋮ & ⋮ \\ 0 & 0 & ⋯ & {w}_{Mx} & 0 \\ 0 & 0 & ⋯ & 0 & {w}_{My}\end{matrix} ]}_{[ 2 M \times 2 M ]} \qquad [ Equation 2 ]$$

Here, wᵢₓ or w_{iy} represents an x-axis directional weight or a y-axis directional weight of the i^{th} feature point.

t=(S^{T}WS)⁻¹(S^{T}W)d [Equation 3]

A total error E obtained by summing all errors in which the weights are reflected is represented by Equation 4 below.

$$E = {\sum }_{i = 1}^{M} ( \vert {w}_{ix} {Δ}_{ix} \vert + {w}_{iy} {Δ}_{iy} \vert ) \qquad [ Equation 4 ]$$

Since Equation 1 is the equation for calculating an approximate value, and correlation between the tuning screws is not included, the feature points may not reach the desired positions only by transferring the tuning screw once. Accordingly, the aforementioned process is repeated until it reaches the desired performance or reaches the set number of times.

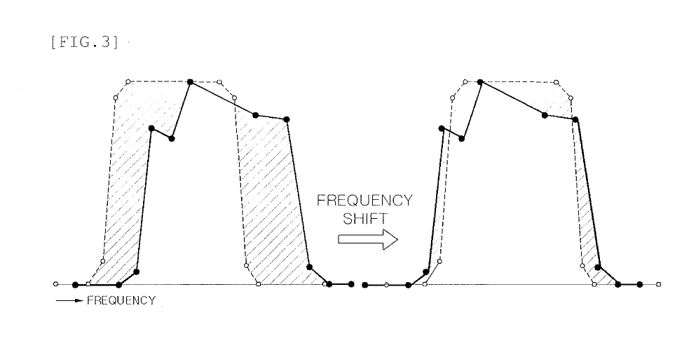

FIG. 3 is a diagram for describing similarity in curves according to an exemplary embodiment of the present invention.

As illustrated in FIG. 3, the two curves cross each other and a plurality of closed polygons is generated. The similarity between the two curves may be discriminated by shape similarity and value similarity.

Here, a dotted line represents the first target S parameter curve, and a solid line represents the first S parameter curve.

In this case, a sum of polygonal regions is in inverse proportion to the similarity, and the sum is referred to as value similarity. Minimum value similarity is obtained by moving one between the two curves along a frequency axis, and the minimum value similarity is referred to as shape similarity. Here, the shape similarity is independent of the relative positions of the two curves.

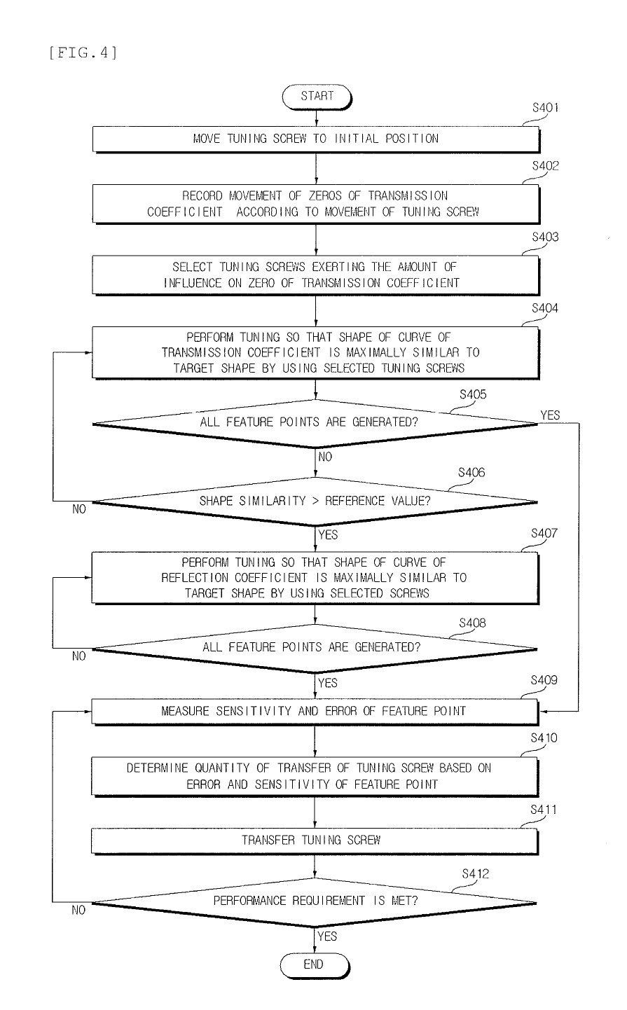

FIG. 4 is a diagram illustrating a method of tuning a microwave filter according to an exemplary embodiment of the present invention.

As illustrated in FIG. 4, the control device according to the present invention may move tuning screws of the high frequency filter to initial positions (S401), and then record movements of zeros of transmission coefficients according to the movements of the tuning screws (S402).

Next, the control device may selectively select a tuning screw which exerts the amount of influence on the zero of the transmission coefficient based on the movement of the zero of the transmission coefficient (S403). In this case, the control device may list the tuning screws in order of the amount of influence exerted on the zero of the transmission coefficient, and then select the preset number of tuning screws.

Next, the control device may perform first coarse tuning by using the selected tuning screws so that a shape of a first S parameter curve corresponding to a curve line of a transmission coefficient is matched to a shape of a first target S parameter curve (S404). That is, the control device performs the first coarse tuning by moving the selected tuning screws so that the shape of the first S parameter curve is matched to the shape of the first target S parameter curve.

Next, the control device may identify whether all feature points are generated after the first coarse tuning (S405).

Next, when all feature points are not generated as a result of the identification, the control device may calculate shape similarity between the first S parameter curve and the first target S parameter curve on which the first coarse tuning has been performed and determine whether the calculated shape similarity is larger than a preset value (S406).

However, when all feature points are generated as a result of the identification, the control device may measure sensitivity and errors of the feature points by moving the pre-selected tuning screws without tuning a shape of a second parameter curve corresponding to a curve of a reflection coefficient.

When the shape similarity is larger than a preset value as a result of the determination, the control device may perform second coarse tuning by using the selected tuning screws so that a shape of the second parameter curve corresponding to the curve of the reflection coefficient is matched to a shape of a second target S parameter curve (S407). That is, the control device performs the second coarse tuning by moving the selected tuning screws so that the shape of the second S parameter curve is matched to the shape of the second target S parameter curve.

However, when the shape similarity is equal to or less than the preset value as a result of the determination, the control device may perform the first coarse tuning by moving the selected tuning screws again so that the shape of the first S parameter curve is matched to the shape of a target S1 parameter curve.

Next, the control device may identify whether all feature points are generated after the second coarse tuning (S408).

Next, when all feature points are generated as a result of the identification, the control device may measure sensitivity and errors of the feature points by moving the preselected tuning screws (S409), and determine the quantity of transfer of the tuning screws by a linear minimum square method in which a weight is assigned (S410).

Next, when the quantity of transfer of the tuning screws is determined, the control device may control so as to move the respective tuning screws based on the determined quantity of transfer of the tuning screws (S411).

Next, the control device may identify whether a performance requirement is satisfied (S412). That is, when the performance requirement condition is not satisfied, the control device may measure sensitivity and errors of the feature points again.

In the meantime, even if it is described that all of constituent elements constituting the aforementioned exemplary embodiment of the present invention are coupled as a single unit or coupled to be operated as a single unit, the present invention is not necessarily limited to the exemplary embodiment. That is, among the components, one or more constituent elements may be selectively coupled to be operated within the scope of the object of the present invention. Although each of the constituent elements may be implemented as an independent hardware, some or all of the constituent elements may be selectively combined with each other, so that they can be implemented as a computer program having one or more program modules for executing some or all of the functions combined in one or more hardware. Such a computer program may implement the embodiments of the present invention by being stored in a computer readable storage medium, such as a USB memory, a CD disc, and a flash memory, and being read and executed by a computer. A magnetic recording medium, an optical recording medium, a carrier wave medium, or the like may be employed as the storage medium of the computer program.

All terms used herein including technical or scientific terms have the same meanings as meanings which are generally understood by those skilled in the art unless they are differently defined. Terms defined in a generally used dictionary shall be construed that they have meanings matching those in the context of a related art, and shall not be construed in ideal or excessively formal meanings unless they are clearly defined in the present application.

As described above, the exemplary embodiments have been described and illustrated in the drawings and the specification. The exemplary embodiments were chosen and described in order to explain certain principles of the invention and their practical application, to thereby enable others skilled in the art to make and utilize various exemplary embodiments of the present invention, as well as various alternatives and modifications thereof. As is evident from the foregoing description, certain aspects of the present invention are not limited by the particular details of the examples illustrated herein, and it is therefore contemplated that other modifications and applications, or equivalents thereof, will occur to those skilled in the art. Many changes, modifications, variations and other uses and applications of the present construction will, however, become apparent to those skilled in the art after considering the specification and the accompanying drawings. All such changes, modifications, variations and other uses and applications which do not depart from the spirit and scope of the invention are deemed to be covered by the invention which is limited only by the claims which follow.

What is claimed is:

1. An apparatus for tuning a microwave filter, comprising:
a measurement device configured to measure a scattering (S) parameter curve of a microwave filter desired to be tuned;
a control device configured to perform tuning so that a shape of the S parameter curve according to a movement of a preselected tuning screw is matched to a shape of a target S parameter curve, and then determine a quantity of transfer of the tuning screw based on feature points on the S parameter curve by using a least squares method in which a preset weight is reflected; and
a tuning device configured to move the tuning screw based on the determined quantity of transfer of the tuning screw.

2. The apparatus of claim 1, wherein the control device moves the tuning screws of the microwave filter to initial positions, records movements of the feature points on the S parameter curve according to the movements of the tuning screws, and then selectively selects the tuning screws in order of the amount of influence exerted on the feature points according to the movements of the feature points.

3. The apparatus of claim 1, wherein the control device comprises:
a coarse tuning unit configured to perform tuning so that a first S parameter curve corresponding to a curve of a transmission coefficient according to a movement of a tuning screw is matched to a first target S parameter curve, and then perform tuning so that a second S parameter curve corresponding to a curve of a reflection coefficient is matched to a second target S parameter curve; and
a fine tuning unit configured to, when feature points positioned on the second S parameter curve are generated as many as the number of feature points on the second target S parameter curve, measure sensitivity and errors of the generated feature points on the second S parameter curve, and determine a quantity of movement of the tuning screw by a least squares method in which a weight is reflected based on the measured sensitivity and error.

4. The apparatus of claim 3, wherein the coarse tuning unit moves the tuning screws of the microwave filter to initial positions, records movements of zeros of transmission coefficient according to the movements of the tuning screws, and then selectively selects the tuning screws in order of the amount of influence exerted on the zeros of the transmission coefficient based on the movements of the zeros of the transmission coefficient.

5. The apparatus of claim 3, wherein the coarse tuning unit performs a first coarse tuning so that a shape of the first S parameter curve is matched to a shape of the first target S parameter curve by moving the tuning screws,
calculates shape similarity between the first S parameter curve on which the first coarse tuning is performed and the curve of the first target S parameter curve and determines whether the calculated shape similarity is larger than a preset value when all feature points are not generated after the first coarse tuning, and
performs a second coarse tuning by moving the tuning screw so that a shape of the second S parameter curve is matched to a shape of the second target S parameter curve when the shape similarity is larger than the preset value as a result of the determination.

6. The apparatus of claim 5, wherein the coarse tuning unit performs the first coarse tuning by moving the tuning screws again so that the shape of the first S parameter curve is matched to the shape of the first target S parameter curve, when the shape similarity is equal to or smaller than the preset value as a result of the determination.

7. The apparatus of claim 5, wherein the coarse tuning unit measures sensitivity and errors of the feature points on the second S parameter curve by moving the tuning screws, and determines a quantity of transfer of the tuning screws based on the measured sensitivity and errors by a least squares method in which a weight is reflected, when all feature points are generated after the first coarse tuning.

8. The apparatus of claim 1, wherein the feature points include at least one among zeros of a transmission coefficient, zeros of a reflection coefficient, and a local maximum point within a bandwidth.

9. A method of tuning a microwave filter, comprising:
measuring a scattering (S) parameter curve of a microwave filter desired to be tuned;
performing tuning so that a shape of the S parameter curve according to a movement of a preselected tuning screw is matched to a shape of a target S parameter curve, and then determining a quantity of transfer of the tuning screw based on feature points on the S parameter curve by using a least squares method in which a preset weight is reflected; and
moving the tuning screw based on the determined quantity of transfer of the tuning screw.

10. The method of claim 9, wherein the performing comprises:
moving the tuning screws of the microwave filter to initial positions,
recording movements of the feature points on the S parameter curve according to the movements of the tuning screws, and
selectively selecting the tuning screws in order of the amount of influence exerted on the feature points according to the movements of the feature points.

11. The method of claim 9, wherein the performing comprises:
performing tuning so that a first S parameter curve corresponding to a curve of a transmission coefficient according to a movement of the tuning screw is matched to a first target S parameter curve, and performing tuning so that a second S parameter curve corresponding to a curve of a reflection coefficient is matched to a second target S parameter curve; and
measuring sensitivity and errors of the generated feature points on the second S parameter curve, and determining a quantity of movement of the tuning screw by a least squares method in which a weight is reflected based on the measured sensitivity and error, when feature points positioned on the second S parameter curve are generated as many as the number of feature points on the second target S parameter curve.

12. The method of claim 11, wherein the performing comprises:
moving the tuning screws of the microwave filter to initial positions,
recording movements of zeros of transmission coefficient according to the movements of the tuning screws, and
selectively selecting the tuning screws in order of the amount of influence exerted on the zeros of the transmission coefficient based on the movements of the zeros of the transmission coefficient.

13. The method of claim 11, wherein the performing comprises:
performing first coarse tuning that a shape of the first S parameter curve is matched to a shape of the first target S parameter curve by moving the tuning screws,
calculating shape similarity between the first S parameter curve on which the first coarse tuning is performed and the curve of the first target S parameter curve is performed when all feature points are not generated after the first coarse tuning and determining whether the calculated shape similarity is larger than a preset value, and
moving the tuning screw and performing second coarse tuning that a shape of the second S parameter curve is matched to a shape of the second target S parameter curve, when the shape similarity is larger than the preset value as a result of the determination.

14. The method of claim 13, wherein the performing comprises:
moving the tuning screws again and performing the first coarse tuning that the shape of the first S parameter curve is matched to the shape of a target S1 parameter curve, when the shape similarity is equal to or smaller than the preset value as a result of the determination.

15. The method of claim 13, wherein the performing comprises:
measuring sensitivity and errors of the feature points on the second S parameter curve by moving the tuning screws, and determining a quantity of transfer of the tuning screws based on the measured sensitivity and errors by a least squares method in which a weight is reflected when all feature points are generated after the first coarse tuning.

16. The method of claim 9, wherein the feature points include at least one among zeros of a transmission coefficient, zeros of a reflection coefficient, and a local maximum point within a bandwidth.
